(19) United States
(12) Patent Application Publication
(10) Pub. No.: US 2017/0057372 A1
(43) Pub. Date: Mar. 2, 2017

(54) ELECTRIC OR HYBRID VEHICLE BATTERY PACK VOLTAGE MEASUREMENT

(71) Applicant: Ford Global Technologies, LLC, Dearborn, MI (US)

(72) Inventors: Michael Edward LOFTUS, Northville, MI (US); Xu WANG, Northville, MI (US); Benjamin A. TABATOWSKI-BUSH, South Lyon, MI (US)

(21) Appl. No.: 14/835,034

(22) Filed: Aug. 25, 2015

(51) Int. Cl. B60L 11/18; G01R 31/36

(52) U.S. Cl. CPC B60L 11/1864; B60L 11/1816; G01R 31/362

(57) ABSTRACT

Systems and methods for measuring voltage of a battery pack for an electrified vehicle, such as an electric or hybrid vehicle, include measuring individual cell voltages and using the individual measurements to periodically update an adjustment or offset applied to the battery pack measurement to improve accuracy of the battery pack measurement. Individual cell voltage measurements may be periodically sampled and combined with the result compared to the pack voltage under predetermined operating conditions, such as when voltage changes or variation are small. A sliding window of voltage differences that satisfy one or more specified conditions, such as being within a range of a previously determined value, may be used to generate the adjustment or offset.

### TECHNICAL FIELD

Aspects of the present disclosure relate to systems and methods for improving accuracy of battery pack voltage measurements for electrified vehicles, such as electric and hybrid vehicles.

### BACKGROUND

Electrified vehicles, such as electric and hybrid vehicles, include a battery pack, also referred to as a traction battery or traction battery pack, and an electric machine to propel the vehicle. Hybrid vehicles include an internal combustion engine that may be used to charge the battery pack and/or propel the vehicle in combination with the electric machine. The traction battery pack includes multiple individual battery cells connected to one another to provide power to the vehicle. A Battery Management System (BMS) in electrified vehicles measures voltage of the traction battery pack as well as individual cell voltages. Battery pack voltage is often used in many aspects of vehicle and battery control, e.g. battery online power capability estimation, cell balancing, battery overcharge and over-discharge protection, engine cranking availability determination (in hybrid vehicles), battery end of life judgment, current leakage measurement, contactor status determination, battery charging, etc.

Because of the higher operating voltages of a traction battery relative to an auxiliary battery, a measurement system for typical traction battery pack voltages is capable of measuring hundreds of volts. However, the required range of battery pack voltage measurements often results in compromises with respect to accuracy of the measurements to provide acceptable cost and complexity of the system for large-scale production. Accuracy of battery pack voltage measurements across the range of operation may impact various control functions for the battery and vehicle. A measurement system with full-scale range and desired accuracy to provide quality control functions often results in a relatively expensive hardware solution. This extra hardware cost is seen on a per-unit basis.

### SUMMARY

Systems and methods for battery pack voltage measurement in electrified vehicles according to various embodiments of the present disclosure use battery cell voltage sensors to improve accuracy of battery pack voltage measurement. A battery pack voltage sensor offset correction is determined based on individual battery cell measurements relative to the battery pack voltage measurement under specified operating conditions.

In various embodiments according to the present disclosure, a vehicle includes a battery pack having individual cells, and an electric machine powered by the battery pack to propel the vehicle. The vehicle includes a control module or controller programmed to control the battery and/or vehicle in response to a published pack voltage using a pack voltage offset, updated when a battery pack voltage change, variation, or frequency is low or small, and based on a difference between the battery pack voltage and a sum of voltages of the individual cells. The vehicle may also include an internal combustion engine coupled to the electric machine. Embodiments may include a controller programmed to calculate a dV/dt based on sampling the battery pack voltage. The controller may also be programmed to calculate the battery pack voltage offset based on a plurality of difference values, each difference value corresponding to the difference between the battery pack voltage and the sum of voltages of the individual cells for a corresponding periodic measurement or sample. The battery pack voltage may be published for use by one or more vehicle or battery controllers with the published pack voltage based on combining a measured battery pack voltage with the battery pack voltage offset. The controller may store difference values corresponding to the difference between the battery pack voltage and the sum of voltages of the individual cells for corresponding periodic measurements and compute a sliding window average of the difference values.

In one or more embodiments, a vehicle processor or controller is configured or programmed to update a battery pack voltage offset based on a sliding window average of stored difference values corresponding to the difference between the battery pack voltage and the sum of voltages of the individual battery cells for corresponding periodic samples or measurements. The controller may discard difference values that exceed a corresponding difference threshold, which may be calculated based on standard deviation of the stored difference values. The vehicle processor or controller may store one or more difference values corresponding to the difference between the battery pack voltage and the sum of voltages of the individual cells in persistent, non-transitory memory for use after a subsequent vehicle key-on event.

Embodiments according to the present disclosure also include a control method for a vehicle having a battery pack including battery cells coupled to a control module programmed to perform the method and control the vehicle. The control method may include adjusting, by the control module, a voltage offset based on an average difference between measured battery pack voltage and a sum of measured battery cell voltages, and combining the voltage offset with the measured battery pack voltage for use in controlling the battery or vehicle. The control method may also include adjusting the voltage offset only when the measured battery pack voltage variation or frequency is small or below an associated threshold. In various embodiments, the control method includes calculating battery pack voltage variation based on differences between adjacent samples divided by a sample time, which may include calculating or estimating a time derivative of the pack voltage. The control method may include, in some embodiments, calculating, by the control module, the average difference between the measured battery pack voltage and the sum of the measured voltages of the individual cells using only difference values that are within a predetermined range, which may be based on plus/minus three standard deviations of difference values used to determine a current average difference. The average difference may be based on a sliding window of difference values, each difference value being within a range based on a standard deviation of previous difference values.

Other embodiments according to the present disclosure include a computer program product embodied in a non-transitory computer readable storage medium having instructions for programming a processor to control a vehicle having a battery pack with individual battery cells. The computer program product may include instructions for monitoring measured battery pack voltage variation and adjusting the measured battery pack voltage by an offset based on a difference between the measured pack voltage and a sum of voltages of the individual battery cells when the variation is below a threshold to improve the accuracy of battery pack voltage measurements. The computer program product may also include instructions for updating the offset based on an average difference between the measured pack voltage and the sum of voltages of the individual battery cells, and instructions for calculating the an average difference value between the measured pack voltage and a the sum of voltages using a sliding window of samples including only difference values that are within a range of previously determined difference values. One or more embodiments of the computer program product may include instructions for calculating a derivative of the measured battery pack voltage to monitor the measured battery pack voltage variation.

Embodiments according to the present disclosure may provide one or more advantages. For example, embodiments according to the present disclosure may improve accuracy of battery pack voltage measurements or determinations used in a variety of battery and vehicle control functions across the range of operating voltages encountered for electric vehicles, including hybrid vehicles. The improved accuracy may be provided using existing sensors or hardware by a programmed processor or controller such that no additional hardware costs are incurred.

### BRIEF DESCRIPTION OF THE DRAWINGS

FIG. 1 is a block diagram of a representative electric vehicle having a vehicle processor or controller that controls the vehicle using a published battery pack voltage based on a voltage offset according to embodiments of the present disclosure;

FIG. 2 is a block diagram illustrating a representative embodiment of a vehicle traction battery pack with battery pack and individual cell voltage sensor modules according to embodiments of the present disclosure;

FIG. 3 is a block diagram illustrating functions of a representative battery cell monitor IC for a traction battery pack for use in determining a voltage offset according to embodiments of the present disclosure; and

FIG. 4 is a block diagram illustrating operation of a system or method for controlling an electric vehicle including updating a battery pack voltage offset according to embodiments of the present disclosure.

### DETAILED DESCRIPTION

As required, detailed embodiments are disclosed herein; however, it is to be understood that the disclosed embodiments are merely representative of the claimed subject matter and may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the embodiments. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

The embodiments of the present disclosure generally provide for a plurality of circuits or other electrical devices. All references to the circuits and other electrical devices and the functionality provided by each, are not intended to be limited to encompassing only what is illustrated and described herein. While particular labels may be assigned to the various circuits or other electrical devices disclosed, such labels are not intended to limit the scope of operation for the circuits and the other electrical devices. Such circuits and other electrical devices may be combined with each other and/or separated in any manner based on the particular type of electrical implementation that is desired. It is recognized that any circuit or other electrical device disclosed herein may include any number of microprocessors, integrated circuits, non-transitory memory devices (e.g., FLASH, random access memory (RAM), read only memory (ROM), electrically programmable read only memory (EPROM), electrically erasable programmable read only memory (EEPROM), or other suitable variants thereof) and software which cooperate with one another to perform operation(s) disclosed herein. In addition, any one or more of the electric devices may be configured to execute a computer program that is embodied in a non-transitory computer readable storage medium that includes instructions to program a computer or controller to perform any number of the functions as disclosed.

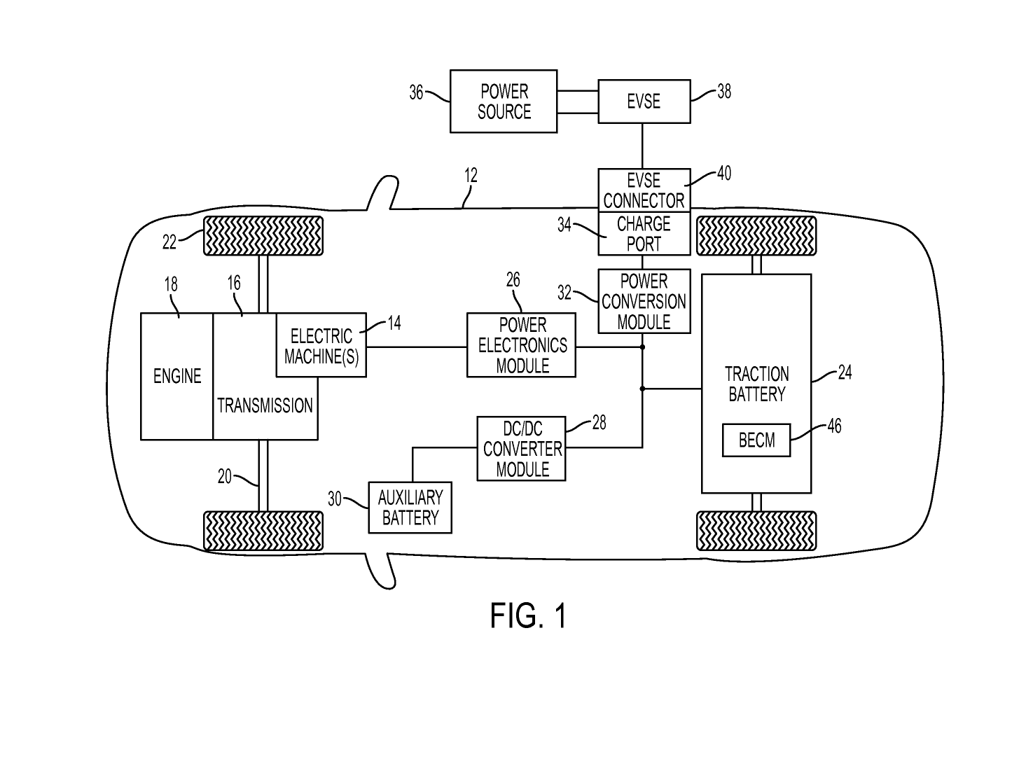

FIG. 1 is a block diagram of a representative electric vehicle having a vehicle processor or controller that controls the vehicle using a published battery pack voltage based on a voltage offset according to embodiments of the present disclosure. While a plug-in hybrid vehicle having an internal combustion engine is illustrated in this representative embodiment, those of ordinary skill in the art will recognize that the disclosed embodiments may also be implemented in a conventional hybrid vehicle, an electric vehicle, or any other type of vehicle having a battery pack with individual battery cells used to propel the vehicle under at least some operating conditions.

A plug-in hybrid-electric vehicle 12 may comprise one or more electric machines 14 mechanically connected to a hybrid transmission 16. The electric machines 14 may be capable of operating as a motor or a generator. For hybrid vehicles, a transmission 16 is mechanically connected to an internal combustion engine 18. The transmission 16 is also mechanically connected to a drive shaft 20 that is mechanically connected to the wheels 22. The electric machines 14 can provide propulsion and deceleration capability whether or not the engine 18 is operating. The electric machines 14 also act as generators and can provide fuel economy benefits by recovering energy that would normally be lost as heat in the friction braking system. The electric machines 14 may also reduce vehicle emissions by allowing the engine 18 to operate at more efficient speeds and allowing the hybrid-electric vehicle 12 to be operated in electric mode with the engine 18 off under certain conditions. Similar advantages may be obtained with an electric vehicle that does not include an internal combustion engine 18.

A fraction battery or traction battery pack 24 stores energy in a plurality of individual battery cells connect together that can be used by the electric machines 14. A vehicle battery pack 24 typically provides a high voltage DC output, although the voltage and current may vary depending on particular operating conditions and loads. The fraction battery pack 24 is electrically connected to one or more power electronics modules. One or more contactors (not shown) may isolate the traction battery pack 24 from other components when opened, and connect the traction battery pack 24 to other components when closed. The power electronics module 26 is also electrically connected to the electric machines 14 and provides the ability to bi-directionally transfer energy between the traction battery pack 24 and the electric machines 14. For example, a typical traction battery pack 24 may provide a DC voltage while the electric machines 14 may require a three-phase AC current to function. The power electronics module 26 may convert the DC voltage to a three-phase AC current as required by the electric machines 14. In a regenerative mode, the power electronics module 26 may convert the three-phase AC current from the electric machines 14 acting as generators to the DC voltage required by the traction battery pack 24. The description herein is equally applicable to a battery electric vehicle (BEV), where the hybrid transmission 16 may be a gear box connected to an electric machine 14 and the engine 18 may be omitted as previously described.

In addition to providing energy for propulsion, the traction battery pack 24 may provide energy for other vehicle electrical systems. A typical system may include a DC/DC converter module 28 that converts the high voltage DC output of the traction battery 24 to a low voltage DC supply that is compatible with other vehicle loads. Other high-voltage loads, such as compressors and electric cabin or component heaters, may be connected directly to the high-voltage without the use of a DC/DC converter module 28. The low-voltage systems may be electrically connected to an auxiliary battery 30 (e.g. a 12V, 24V, or 48V battery).

Embodiments of this disclosure may include vehicles such as vehicle 12, which may be a hybrid or range-extender hybrid, or an electric vehicle or a plug-in hybrid vehicle in which the traction battery pack 24 may be recharged by an external power source 36. The external power source 36 may be a connection to an electrical outlet connected to the power grid. The external power source 36 may be electrically connected to electric vehicle supply equipment (EVSE) 38. The EVSE 38 may provide circuitry and controls to regulate and manage the transfer of energy between the power source 36 and the vehicle 12. The external power source 36 may provide DC or AC electric power to the EVSE 38. The EVSE 38 may have a charge connector 40 for plugging into a charge port 34 of the vehicle 12. The charge port 34 may be any type of port configured to transfer power from the EVSE 38 to the vehicle 12. The charge port 34 may be electrically connected to a charger or on-board power conversion module 32. The power conversion module 32 may condition the power supplied from the EVSE 38 to provide the proper voltage and current levels to the traction battery 24. The power conversion module 32 may interface with the EVSE 38 to coordinate the delivery of power to the vehicle 12. The EVSE connector 40 may have pins that mate with corresponding recesses of the charge port 34. Alternatively, various components described as being electrically connected may transfer power using a wireless inductive coupling.

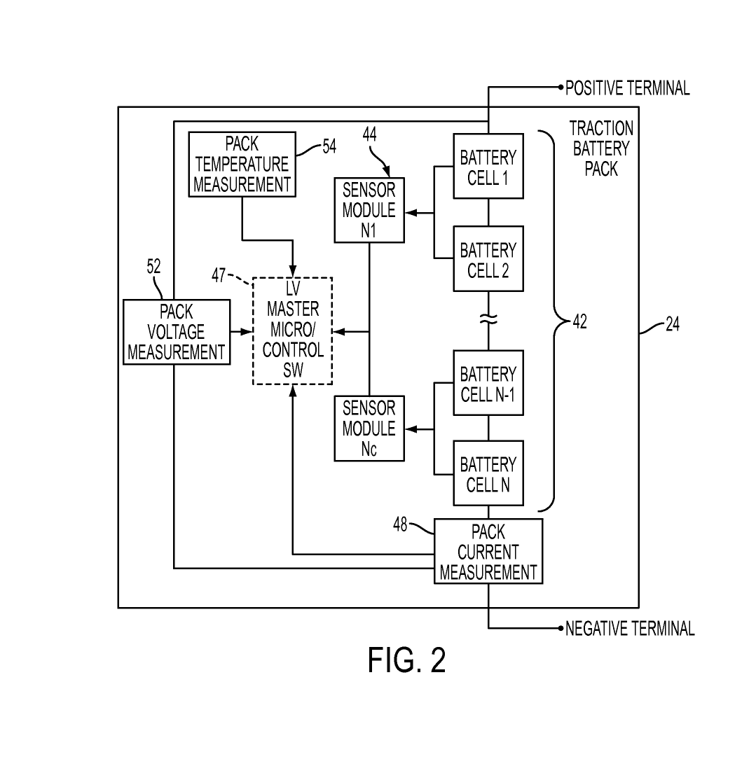

The various components illustrated in FIG. 1 may have one or more associated controllers to control and monitor the operation of the components. The controllers may communicate via a serial bus (e.g., Controller Area Network (CAN)) or via discrete conductors. As described in greater detail below, various operating parameters or variables may be broadcast or published using the CAN or other conductors for use by other vehicle control modules or sub-modules in controlling the vehicle or vehicle components, such as the traction battery pack 24. One or more controllers may operate in a stand-alone manner without communication with one or more other controllers. As described in greater detail with reference to FIGS. 2-4, one of the controllers may be implemented by a Battery Energy Control Module (BECM) 46 to control various charging and discharging functions, battery cell charge balancing, battery pack voltage measurements, individual battery cell voltage measurements, battery over-charge protection, battery over-discharge protection, battery end-of-life determination, etc. In one embodiment, the BECM 46 is programmed to adjust a voltage offset based on an average difference between measured battery pack voltage and a sum of measured battery cell voltages, combine the voltage offset with the measured battery pack voltage, and publish the combined voltage value for use in controlling the vehicle. The BECM 46 may be positioned within traction battery pack 24 and may communicate with various types of non-transitory computer readable storage media including persistent and temporary storage devices to store battery voltage measurements and related statistics, which may include an average, standard deviation, associated thresholds, etc.

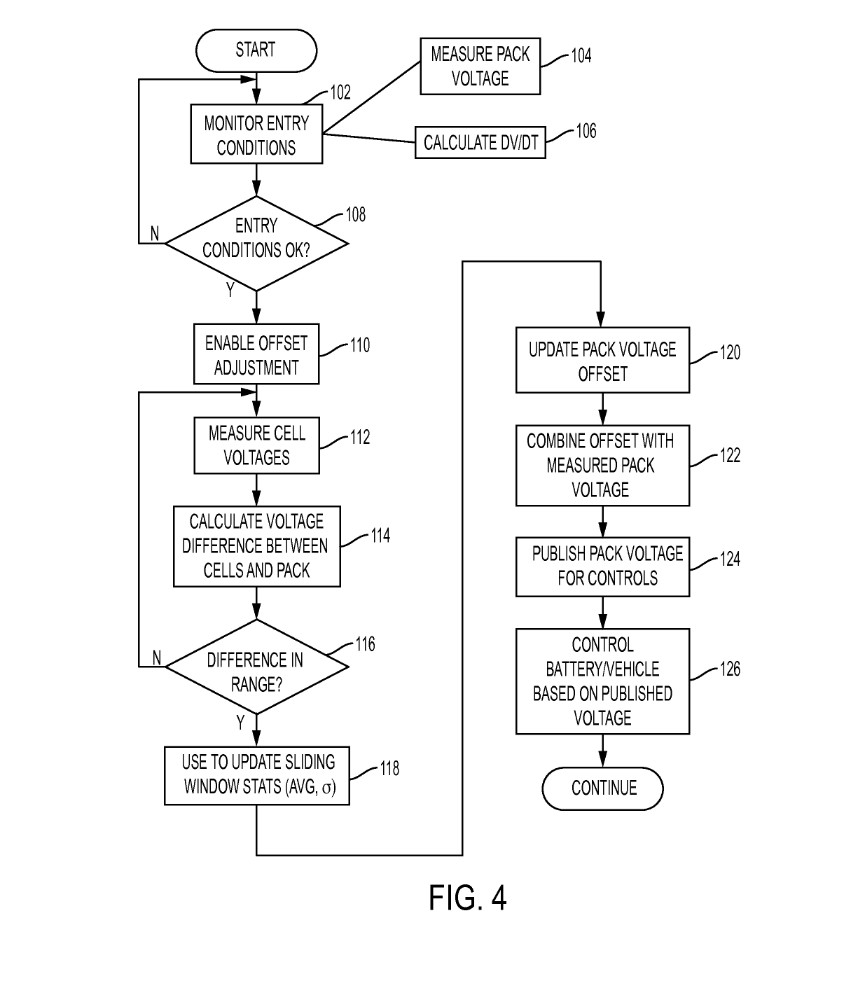

Vehicle traction battery packs may be constructed using a variety of physical arrangements or architectures and various chemical formulations. Typical battery pack chemistries include lead-acid, nickel-metal hydride (NIMH), or Lithium-Ion. FIG. 2 shows a typical traction battery pack 24 in a simple series configuration of a plurality of individual battery cells 42. Other battery packs, however, may be composed of any number of individual battery cells connected in series, in parallel, or some combination thereof. As previously described, a typical system may have one or more controllers, such as BECM 46 and LV Master Micro 47 that monitor and control various functions of the fraction battery pack 24. The BECM 46, LV Master Micro 47 and/or other controllers or control modules may monitor several battery pack bulk characteristics such as battery pack current 48, battery pack voltage 52 and battery pack temperature 54 as well as characteristics associated with individual battery cells 42. Each controller or control module may have non-volatile memory such that data may be retained when the controllers in an off condition for use after a subsequent key-on event as previously described. Similarly, the controller(s) may include integrated non-transitory computer readable storage containing instructions for programming the controller(s) or associated processor(s) to control battery pack 24 and/or vehicle 12 that include instructions for monitoring measured battery pack voltage variation based on battery pack voltage measurements 52, and instructions for adjusting the measured battery pack voltage by an offset based on a difference between the measured battery pack voltage and a sum of voltages of the individual battery cells 42 when the pack voltage change or variation is below a threshold as described in greater detail with reference to FIG. 4.

In various embodiments, the BECM 46 measures battery pack voltage and cell voltages at different sampling rates. The battery pack voltage may be measured faster or more frequently than that for individual cell voltages. Due to the different sampling rates etc., the battery pack voltage measurement and individual cell voltage measurements (or groups of cells) may have different filter designs (both hardware filters and digital filters). However, for the low frequency components, especially for the DC component of the voltages, the output values of these two filters are very close to each other.

The BECM 46 may include hardware and/or software to control various battery functions, such as battery cell charge balancing, battery thermal conditioning, individual battery cell voltage measurement, and battery pack voltage measurement, for example. As generally understood by those of ordinary skill in the art, charge balancing may be more important for some battery chemistries than others, but is performed to balance the individual charges of each battery cell by discharging cells that are charged above a desired threshold level, and charging cells that have a charge below the desired threshold level. In many applications, the cell voltage sensors have much higher accuracy than the battery pack voltage sensor. The present disclosure recognizes that the sum of the cell voltage sensor error for N cells may be significantly less than the error of the relatively expensive battery pack voltage sensor. As such, according to various embodiment of the present disclosure, the sum of the cell voltage measurements is a better indication of pack voltage when the pack voltage change or variation is small.

In addition to monitoring the battery pack bulk characteristics, BECM 46 may also monitor and/or control cell-level characteristics, such as individual or grouped cell voltages that may be used during charge balancing and/or to determine a published battery pack voltage as described herein. For example, the terminal voltage, current, and temperature of each cell may be measured. A battery controller, implemented by BECM 46 in this embodiment, may include voltage monitoring circuits or sensor modules 44 to measure the voltage across the terminals of each of the N cells 42 of the battery pack 24. In one embodiment, the BECM 46 is programmed to control the vehicle in response to a published battery pack voltage using a battery pack voltage offset, updated when a filtered battery pack voltage is below a threshold, and based on a difference between the battery pack voltage and a sum of voltages of the individual cells, as described in greater detail with reference to FIG. 4. The filtered battery pack voltage may be used to measure the change or variation of the battery pack voltage over a predetermined time period.

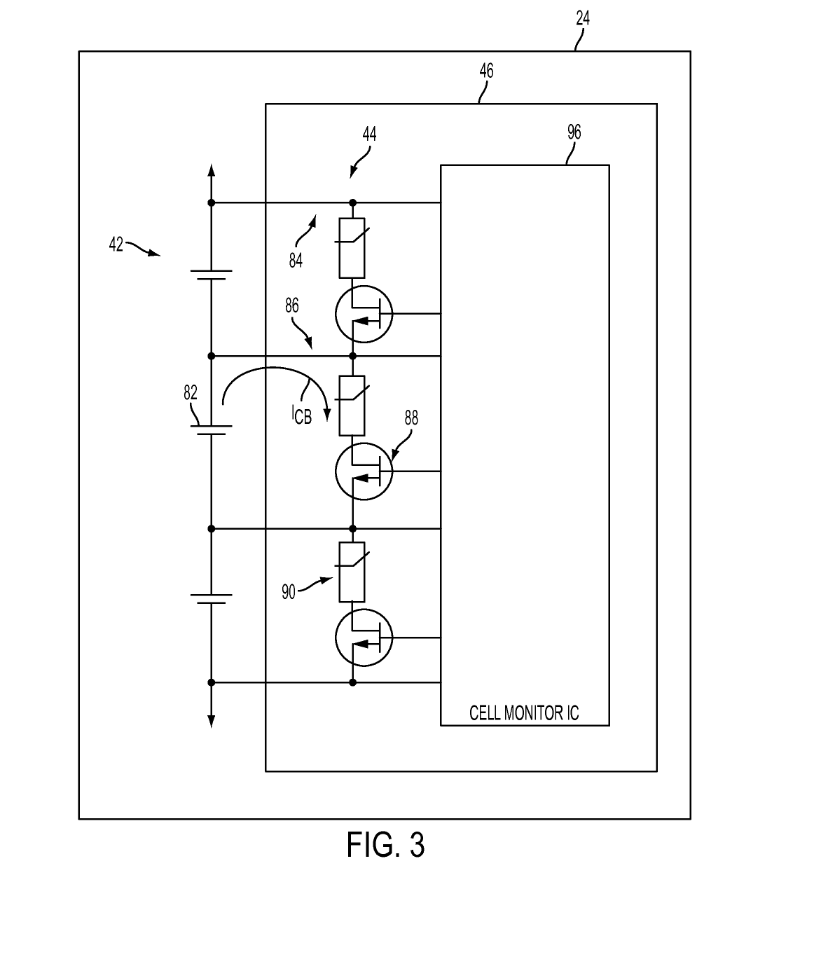

Referring now to FIG. 3, a block diagram of a representative battery pack 24 having a sensor module 44 associated with one or more individual battery cells 42 used in determining and/or publishing a battery pack voltage for use in various battery or vehicle controls is shown. Battery pack 24 includes a plurality of battery cells 42. Although only three cells connected to a single cell monitor IC are shown, those of ordinary skill in the art will recognize that traction battery packs often include dozens or hundreds of cells that may be arranged in one or more groups, bricks, or blocks of cells with each group, brick, or block having an associated cell monitor IC or sensor module 44 (as illustrated in FIG. 2). Likewise, although battery cells 42 are illustrated as individual cells 82 connected in series and having voltage sense leads 84, 86 and a charge balance switching connection 88, other arrangements may be provided depending on the particular application and implementation. As such, battery pack voltage determination based on an offset calculated by a battery or vehicle controller as described herein may be implemented by or applied to various other types of arrangements or groupings of individual battery cells 82.

As previously described, BECM 46, or one or more similar controllers, may be located within battery pack 24. Alternatively, BECM 46 may be located outside of battery pack 24, but controlling one or more circuit devices 90, such as charge balance resistors or positive temperature coefficient devices, for example, disposed within battery pack 24. Each cell 82 may include an associated voltage cell sense lead 86 and charge balance switch 88, implemented by a transistor or similar device activated by hardware and/or software control logic within a cell monitor integrated circuit (IC) 96. Cell monitor IC 96 measures individual cell voltages, reports cell voltages to control logic within BECM 46, and periodically performs cell balancing and/or thermal conditioning. As described in greater detail with respect to FIG. 4, BECM 46 may use the individual cell voltage measurements to determine a battery pack voltage offset to improve the accuracy of the battery pack voltage measurement across the range of operation.

Referring now to FIG. 4, a block diagram illustrating operation of a system or method for controlling an electric vehicle including updating a battery pack voltage offset according to embodiments of the present disclosure is shown. With regard to the processes, systems, methods, heuristics, etc. described herein, it should be understood that, although the steps of such processes, etc. may be described as occurring in an ordered sequence, such processes could be performed with the described steps completed in an order other than the order described herein. It should also be understood that certain steps could be performed simultaneously, that other steps could be added, or that certain steps described herein could be omitted while keeping with the teachings of this disclosure and being encompassed by the claimed subject matter. In other words, the descriptions of methods or processes are provided for the purpose of illustrating certain embodiments, and should be understood to be representative of one of many variations and not limited to only those shown or described.

As illustrated at 102, various battery and/or vehicle conditions may be monitored to identify operating conditions suitable for updating the battery pack voltage offset, which is based on the voltages of individual battery cells and/or groups or blocks of cells depending on the particular application and implementation. In the representative embodiment illustrated in FIG. 4, monitoring entry conditions 102 may include measuring the battery pack voltage at 104 and calculating one or more associated statistics using the BECM or another vehicle controller or control module, such as a time derivative of the voltage as represented at 106. In one embodiment, battery pack voltage change or variation is determined or represented by calculating the derivative with respect to time. The following Savitzky Golay Filter can be used as a digital filter within the BECM software to estimate or determine the derivative of battery pack voltage with respect to time:

$$\frac{d v ( k )}{d t} = [ 4 * v ( k + 4 ) + 3 * v ( k + 3 ) + 2 * v ( k + 2 ] + v ( k + 1 ) + v ( k ) - v ( k - 1 ) - 2 * v ( k - 2 ) - 3 * v ( k - 3 ) - 4 * v ( k - 4 ) ] / ( 60 * h ) \qquad ( 1 )$$

where: h is the sampling period; k is the time index for a corresponding voltage measurement or sample; v is the battery pack voltage measurement; and dv/dt is the voltage time derivative.

One or more entry conditions may be compared to corresponding criteria or thresholds as represented by block 108. In the time domain, low frequency voltage variation will have a small time derivative. If the voltage change over the time period is below a corresponding threshold, the result of block 108 is “Y” indicating that conditions are acceptable to update the battery pack voltage offset. In one embodiment, block 108 represents control logic or software for setting or clearing a flag, called OFFSET_CORRECT_ENABLE, according to the following logic operation:
IF (abs(dv/dt)<=ε)
   {OFFSET_CORRECT_ENABLE=TRUE;}
ELSE
   {OFFSET_CORRECT_ENABLE=FALSE;}
      where: ε is a small positive predetermined calibration value corresponding to the associated voltage change threshold or entry condition criterion to enable the battery pack voltage offset adjustment as represented at block 110.

Voltages for individual battery cells or groups/blocks of individual battery cells are periodically measured or sampled by corresponding sensors as represented at block 112. The controller then calculates difference values between the sum of the individual cells (or blocks) and the battery pack voltage measurement as represented at block 114. In one embodiment, at each cell voltage measurement time point k, a new voltage difference VOLTAGE_DIFF value is calculated according to:

IF (OFFSET_CORRECT_ENABLE(k)==TRUE){VOLTAGE_DIFF(k)=Σᵢ₌₁^{M}CELLvᵢ(k)−PACKv(k);} (2)

where CELLvᵢ(k) is the voltage measurement for cell (or block) i at time point k; PACKv(k) is the pack voltage measurement at time point k; M is the total number of individual cells (or blocks) in the battery pack.

As illustrated at block 116 of FIG. 4, the voltage difference values are compared to one or more thresholds to determine if each difference value is within an appropriate calibration range. In one embodiment, the range is set to +/−3 sigma (standard deviations) of the previously determined difference values. In one embodiment, at time point index k, if a new voltage difference VOLTAGE_DIFF(k) is available, then the n voltage difference samples in a sliding window is updated according to the following logic as generally represented by block 118.
IF ((abs(VOLTAGE_DIFF(k)−VOLTAGE_DIFF_AVG(k−1))<3*VOLTAGE_DIFF_DEV(k−1)) AND (OFFSET_CORRECT_ENABLE(k)==TRUE))
   {VOLTAGE_DIFF₁(k)=VOLTAGE_DIFF₂(k−1);
   VOLTAGE_DIFF₂(k)=VOLTAGE_DIFF₃(k−1);
   . . .
   VOLTAGE_DIFFₙ₋₁(k)=VOLTAGE_DIFFₙ(k−1);
   VOLTAGE_DIFFₙ(k)=VOLTAGE_DIFF(k);}
ELSE
   {VOLTAGE_DIFF₁(k)=VOLTAGE_DIFF₁(k−1);
   VOLTAGE_DIFF₂(k)=VOLTAGE_DIFF₂(k−1);
   . . .
   VOLTAGE_DIFFₙ₋₁(k)=VOLTAGE_DIFFₙ₋₁(k−1);
   VOLTAGE_DIFFₙ(k)=VOLTAGE_DIFFₙ(k−1);}
      The above logic represented by blocks 116, 118 may be used to filter out anomalous or noisy measurements by only adding the new measurement to the sliding window measurements if the new measurement is within a predetermined range, 6-sigma in this example, of the last updated voltage difference running average. Otherwise, the sample will be disregarded or discarded and will not be used in the battery pack voltage sensor offset update. The logic provides more reliable calculations by excluding any unusually large voltage difference which could be caused by measurement noise, transient conditions, or other anomalies from the battery pack voltage offset calculation.

Various statistics may be calculated as represented at block 118 using a predetermined number of samples that meet the inclusion criteria represented by block 116. Embodiments may include a sliding or running window with size n used to calculate the statistics of the n samples of voltage differences VOLTAGE_DIFF(k). The running average of the n samples of the voltage difference at each time point k may be calculated as VOLTAGE_DIFF_AVG as follows:

VOLTAGE_DIFF_AVG(k)=Σᵢ₌₁ⁿVOLTAGE_DIFFᵢ(k)/n (3)

where VOLTAGE_DIFF(k) is the i^{th} voltage difference sample in the sliding window at time point k. Similarly, block 118 may include calculating the running standard deviation of the n samples of the voltage difference at time point k represented by VOLTAGE_DIFF_DEV according to:

VOLTAGE_DIFF_DEV(k)={square root over (Σᵢ₌₁ⁿ(VOLTAGE_DIFFᵢ(k)−VOLTAGE_AVG(k))²/n)} (4)

The battery pack voltage offset may then be updated or adjusted as represented at block 120 based on the average difference between the measured battery pack voltage and the sum of the voltages of the individual battery cells. In one embodiment, the battery pack voltage sensor offset VOLTAGE_OFFSET is updated according to:

VOLTAGE_OFFSET(k)=VOLTAGE_DIFF_AVG(k) (5)

The battery pack voltage offset is then combined with the measured battery pack voltage as represented by block 122 and the resulting parameter is published or broadcast as represented at block 124 for use by various battery and/or vehicle control functions or modules as represented by block 126. The published pack voltage may be used in a variety of battery pack control functions and/or vehicle control functions. For example, the published pack voltage may be used for battery online power capability estimation, cell balancing, battery overcharge and over-discharge protection, engine cranking availability determination (in hybrid vehicles), battery end of life judgment, current leakage measurement, contactor status determination, battery charging, etc.

In one embodiment, the battery pack voltage is published for battery control usage according to:

PACK_VOLTAGE_PUBLISHED(k)=PACKv(k)+VOLTAGE_OFFSET(k) (6)

Those of ordinary skill in the art may recognize that calculations similar to those of equations (3) and (4), require that the n samples in the sliding window be saved in non-volatile or persistent memory for use in subsequent power cycles or key-on, key-off cycles for the calculation. While suitable for many applications, persistent memory may be conserved using an approximation or estimate of the running average and standard deviation calculations as follows:

$$\begin{matrix}VOLTAGE\_DIFF \_AVG ( k ) = \frac{( n - 1 ) * VOLTAGE\_DIFF \_AVG ( k - 1 )}{n} + \frac{VOLTAGE\_DIFF ( k )}{n} & ( 7 ) \\ VOLTAGE\_DIFF \_DEV ( k ) = \sqrt{\frac{\begin{matrix}( n - 1 ) * VOLTAGE\_DIFF \_DEV {( k - 1 )}^{2} + \\ {( VOLTAGE\_DIFF ( k ) - VOLTAGE\_DIFF \_AVG ( k ) )}^{2}\end{matrix}}{n}} & ( 8 )\end{matrix}$$

For the approximate method represented by equations (7)-(8), only the two variables VOLTAGE_DIFF_AVG(k−1) and VOLTAGE_DIFF_DEV(k−1) need to be saved in non-volatile memory over power cycles for the calculation.

As described above, embodiments according to the present disclosure may improve accuracy of battery pack voltage measurements or determinations used in a variety of battery and vehicle control functions across the range of operating voltages encountered for electric vehicles, including hybrid vehicles, using voltage measurements of individual battery cells or groups/blocks of cells. The improved accuracy may be provided using existing sensors and hardware by a programmed processor or controller such that no additional hardware costs are incurred.

While representative embodiments are described above, it is not intended that these embodiments describe all possible embodiments within the scope of the disclosure or claimed subject matter. The words used in the specification are words of description rather than limitation, and it is understood that various changes may be made without departing from the spirit and scope of the disclosure. Additionally, the features of various embodiments may be combined to form further embodiment even though particular combinations are not explicitly described or illustrated. Various embodiments may have been described as providing advantages or being preferred over other embodiments or prior art implementations with respect to one or more desired characteristics. However, as one of ordinary skill in the art is aware, one or more features or characteristics may be compromised to achieve desired overall system attributes, which depend on the specific application and implementation. These attributes may include, but are not limited to: cost, strength, security, durability, life cycle cost, marketability, appearance, packaging, size, serviceability, weight, manufacturability, ease of assembly, etc. Embodiments described as less desirable than other embodiments or prior art implementations with respect to one or more characteristics are not outside the scope of the disclosure or claims and may be desirable for particular applications.

What is claimed is:

1. A vehicle, comprising:
a battery pack having individual cells;
an electric machine powered by the battery pack to propel the vehicle; and
a controller programmed to control the battery in response to a published pack voltage that incorporates a pack voltage offset updated after pack voltage variation is less than a threshold and is based on a difference between a measured pack voltage and a sum of voltages of the individual cells.

2. The vehicle of claim 1 further comprising an internal combustion engine coupled to the electric machine.

3. The vehicle of claim 1, the controller further programmed to calculate the pack voltage variation based on a time derivative of the pack voltage.

4. The vehicle of claim 1, the controller further programmed to:
calculate the pack voltage offset based on a plurality of difference values, each difference value corresponding to the difference between the pack voltage and the sum of voltages of the individual cells for a corresponding periodic measurement.

5. The vehicle of claim 1, the controller further programmed to publish the pack voltage for use in controlling the vehicle based on combining a measured pack voltage with the pack voltage offset.

6. The vehicle of claim 1, the controller programmed to:
store difference values corresponding to the difference between the pack voltage and the sum of voltages of the individual cells for corresponding periodic measurements; and
compute a sliding window average of the difference values.

7. The vehicle of claim 6, the controller programmed to update the pack voltage offset based on the sliding window average.

8. The vehicle of claim 6, the controller programmed to discard difference values that exceed a corresponding difference threshold.

9. The vehicle of claim 8, the controller programmed to calculate the corresponding difference threshold based on standard deviation of the stored difference values.

10. The vehicle of claim 1, the controller programmed to store the difference between the measured pack voltage and the sum of voltages of the individual cells in persistent memory for use after a subsequent vehicle key-on event.

11. A control method for a vehicle having a battery pack including battery cells coupled to a processor programmed to perform the method, comprising:
controlling, by the processor, the battery pack using a published pack voltage based on a voltage offset adjusted using an average difference between a measured battery pack voltage and a sum of measured battery cell voltages, the published pack voltage being the voltage offset combined with the measured battery pack voltage.

12. The control method of claim 11 further comprising adjusting the voltage offset only when variation of the measured battery pack voltage is below an associated threshold.

13. The control method of claim 12 wherein the variation of the measured battery pack voltage is calculated by the processor based on a filtered battery back voltage that represents a derivative with respect to time of the battery pack voltage.

14. The control method of claim 11 further comprising calculating, by the processor, the average difference using only difference values that are within a predetermined range.

15. The control method of claim 14 wherein the predetermined range is based on plus/minus three standard deviations of difference values used to determine a current average difference.

16. The control method of claim 11 further comprising calculating the average difference based on a sliding window of difference values, each difference value being within a range based on a standard deviation of previous difference values.

17. A computer program product embodied in non-transitory computer readable storage having instructions for programming a processor to control a vehicle having a battery pack with individual battery cells, comprising instructions for:
monitoring measured battery pack voltage variation; and
adjusting a measured pack voltage by an offset that is updated based on a difference between the measured pack voltage and a sum of voltages of the individual battery cells while the variation is below a threshold.

18. The computer program product of claim 17 further comprising instructions for updating the offset based on an average difference between the measured pack voltage and the sum of voltages of the individual battery cells.

19. The computer program product of claim 17 further comprising instructions for calculating an average difference value between the measured pack voltage and a the sum of voltages using a sliding window of samples including only difference values that are within a range of previously determined difference values.

20. The computer program product of claim 17 further comprising instructions for calculating a derivative of the measured battery pack voltage to monitor the measured battery pack voltage variation.
